(19) United States
(12) Patent Application Publication
(10) Pub. No.: US 2016/0254148 A1
(43) Pub. Date: Sep. 1, 2016

(54) SILICON CARBIDE SEMICONDUCTOR DEVICE AND MANUFACTURING METHOD FOR SAME

(71) Applicant: FUJI ELECTRIC CO., LTD., Kawasaki-shi, kanagawa (JP)

(72) Inventor: Shoji KITAMURA, Matsumoto-shi, Nagano (JP)

(73) Assignee: FUJI ELECTRIC CO., LTD., Kawasaki-shi, Kanagawa (JP)

(21) Appl. No.: 15/027,423

(22) PCT Filed: Sep. 26, 2014
(86) PCT No.: PCT/JP2014/075628

§ 371 Date: Apr. 5, 2016

(30) Foreign Application Priority Data
Oct. 28, 2013 (JP) 2013-222852

(51) Int. Cl. H01L 21/02; H01L 21/04; H01L 29/66; H01L 29/16; H01L 29/32; H01L 29/47; H01L 29/872; H01L 21/265

(52) U.S. Cl. CPC H01L 21/02529; H01L 29/872; H01L 21/02378; H01L 21/02689; H01L 21/046; H01L 21/0495; H01L 21/26506; H01L 29/1608; H01L 29/32; H01L 29/47; H01L 29/6606

(57) ABSTRACT

A method of manufacturing a silicon carbide semiconductor device in which a first-conductivity-type silicon carbide semiconductor epitaxial layer is formed on a main surface of a first-conductivity-type silicon carbide semiconductor substrate, wherein the silicon carbide semiconductor device manufacturing method includes: a step for supplying strain energy to at least one of (i) a surface layer of the surface of the silicon carbide semiconductor substrate on which the silicon carbide semiconductor epitaxial layer is formed, and (ii) the surface of the silicon carbide semiconductor epitaxial layer, a step for forming a carbon film on the surface layer, and a step for forming a recrystallized layer by adding a heat treatment for recrystallizing the surface layer to which the strain energy is supplied.

### TECHNICAL FIELD

The present invention relates to a silicon carbide semiconductor device and a method for manufacturing same related to the reduction of the density of crystal defects in the surface of a silicon carbide epitaxial layer.

### BACKGROUND ART

In recent years, attention has focused on silicon carbide semiconductor devices as devices capable of overcoming limitations in silicon device characteristics. In particular, silicon carbide semiconductor devices are expected to find applications in power semiconductor devices by making the most of such outstanding physical characteristics as a higher breakdown electric field strength (roughly 10 times higher) and higher thermal conductivity (roughly 3 times higher) than silicon semiconductor devices.

These outstanding physical characteristics are a function of the interatomic bond energy of Si and C as being high; however, a problem is that the differences in the periodic structures of Si and C at bonding time result in an abundance of polytypes (crystal polymorphs), such as 2H, 3C, 4H, 6H, and 15R in the crystal, increasing the likelihood of the generation of irregularities during crystal growth. Therefore, a crystal mixture of different polytypes is unavoidable when fabricating a SiC single crystal, and the reality is that crystal defects such as dislocations are likely to occur due to crystal irregularities arising from the formation of polytype crystals. Therefore, an incredibly larger number of crystal defects are found in current SiC semiconductors than in Si semiconductors, which are nearly devoid of dislocations.

It should be noted that because molten SiC is not very stable at high temperatures, a SiC crystal ingot, which is the raw material for a SiC substrate, is difficult to grow from a melt in the same way as Si, and the SiC ingot is generally fabricated using a sublimation technique. A SiC device is fabricated by using as an underlying substrate a SiC semiconductor wafer cut from an ingot fabricated using the sublimation technique, epitaxially growing a SiC layer on the SiC underlying substrate using a gas phase method, and building into the SiC epitaxial layer (hereinafter SiC epilayer) an impurity diffusion layer and a junction structure. Nearly the same process as that for an Si device can be employed in the formation of devices on the SiC epilayer, but the process differs significantly in that practically no dopant atoms are thermally diffused into the SiC underlying substrate and the SiC epilayer, thereby preventing the use of a thermal diffusion method in the formation of the impurity diffusion layer.

Therefore, in the SiC device, it is required to form the diffusion layer using multistage (multiple) high-temperature ion implantation in which ion implantation conditions differ in accordance with the depth of the diffusion layer, and to perform high-temperature heat treatment at 1600° C. or higher in order to activate the impurity diffusion layer.

The SiC device is a vertical device in which an electric current flows in a direction between two main surfaces of the semiconductor substrate, and therefore, when there is a crystal defect in the current path of the semiconductor substrate, the electrical characteristics of the device deteriorate, and the non-defective rate of products drops. For example, in a device such as a SiC-Schottky barrier diode (SiC-SBD) or SiC-MOSFET in particular, because a crystal defect in the surface of the SiC epilayer thereof is directly linked to characteristics degradation, and reliability and quality, reductions in the density of surface defects and the establishment of a method for evaluating surface defect density are important challenges for improving the non-defective rate and reliability of SiC devices.

SiC epilayer surface defects are broadly divided into dislocation defects that extend into the upper-layer epilayer, such as threading screw dislocations (TSD), threading edge dislocations (TED) and the like inherited from the SiC underlying substrate that is a base, and defects (downholes, etc.) that are formed inside the epilayer during epitaxial growth.

FIG. 2(a) schematically shows a cross-section of a SiC semiconductor device in which TSDs, which were formed in the SiC underlying substrate in accordance with a conventional fabrication method for forming a SiC epilayer without introducing a strained layer, have propagated to the epilayer surface as it is, or the type of crystal defect has been converted to a basal plane dislocation (BPD) or carrot defect and propagated to the epilayer surface.

As defects originally in the SiC underlying substrate, dislocation defects called micropipes became a major problem in the 2000's, but today, thanks to improvements in crystal fabrication methods, micropipe defects have been largely eliminated. However, even now, the reality is that TSD and TED dislocation defects exist at a level of roughly 1000/cm², become the starting points for defects, and propagate and extend into the epilayer. There is a need to reduce defects in SiC underlying substrates.

Defects that occur during the formation of the epilayer (downholes and the like) are being reduced by improving epilayer formation apparatuses and formation conditions. Defects extending into and penetrating through the epilayer in succession to dislocation defects such as the aforementioned TSDs and TEDs generated in the SiC underlying substrate are currently still not under full control; in particular, it is practically impossible to control carrot-type defects, which form uneven patterns on a surface. The carrot defects are said to be defects related to screw dislocations and base plane dislocations. These defects are known to be associated with poor electrical characteristics in devices, especially unfavorable leakage current, and are the main cause of drops in the non-defective rate of products.

Next, an overview of a conventional SiC device fabrication process will be explained taking a SiC-SBD as an example. FIG. 5(1) shows a cross-section of a completed SiC-SBD, and FIG. 5(2) shows an overview of the fabrication process therefor.

In step (a) of FIG. 5(2), the Si surface side of an n-type SiC underlying substrate 1 (impurity concentration of greater than 1×10¹⁸ cm⁻³, and substrate thickness of 350 μm) is subjected to chemical mechanical polishing (CMP), and epilayer formation pre-processing is performed.

In step (b) of FIG. 5(2), an n-type SiC epilayer 2 (impurity concentration of approximately 1×10¹⁶ cm⁻³, and substrate thickness of 10 μm) is deposited on the Si surface. The epilayer 2 is grown by CVD at a growth temperature of 1700° C. using SiH₄ and C₃H₈ as the source gases, and H₂ as the carrier gas. Nitrogen (N₂) is used as the n-type dopant.

In step (c) of FIG. 5(2), an SBD peripheral voltage withstanding structure is formed on the surface of the SiC epilayer 2. That is, after the formation of a p-type ion implantation region at a prescribed depth (Xj) using the multistage ion implantation of Al and/or B and so forth, heat treatment is performed at 1600° C., and the implanted ion species is activated to form, as the peripheral voltage withstanding structure, a p-type region 3 having an electric field relaxation function.

In step (d) of FIG. 5(2), after the formation of a Ni vapor deposition film, heat treatment is performed at 1000° C. to form an ohmic Ni silicide film 4 on the back surface side of the SiC underlying substrate 1. Thereafter, subsequent to forming a contact hole for an oxide film 5, a Schottky barrier electrode 6 made of Ti or the like is formed on the surface of the SiC epilayer 2 of the front surface side of the SiC underlying substrate. A silicide layer of Ti silicide or the like is formed at the SiC epilayer 2 junction with the Schottky barrier electrode 6 using heat treatment at around 500° C.

In step (e) of FIG. 5(2), an AlSi electrode film 7 is formed on the front surface side, and a Ti/Ni/Au electrode 8 is formed on the back surface side, respectively, to complete the SBD device.

In the SiC-SBD device fabrication processes explained above, when crystal defects exist in the surface of the SiC epilayer 2 formed using step (b), the formation of a good Schottky junction is impeded when the Ti silicide is formed in step (d), which results in poorer SBD device characteristics.

There is a high risk of SiC epilayer surface defects affecting the quality of the front surface side silicide layer that form the SBD Schottky barrier and/or the MOSFET gate oxide film. In particular, in the SBD, there is the likelihood of the height of the Schottky barrier changing and leakage current increasing in accordance with the generation of defects. Because these surface defects tend to produce step-shaped height differences in the SiC surface, there is also the likelihood of the formation of the silicide layer becoming nonuniform due to these steps, resulting in electric-field concentration points localized. Therefore, in the actual device fabrication process as described above, it has been generally performed that chips in which specific types of defects exist are removed from the fabrication process at the stage where the distribution of epilayer surface defects is evaluated. The type of defect that is found most frequently among these surface defects is the carrot defect. The impact on the non-defective rate of devices as a result of carrot defects in particular has come under study recently, and the relationship to reverse characteristics deterioration are being discussed in particular. As explained hereinabove, various methods for reducing the surface defects in a SiC epilayer are being studied with the aim of improving the non-defective rate of devices, principal among which are methods for improving substrate formation methods.

Regarding methods for reducing crystal defects in order to improve the non-defective rate in the fabrication of SiC devices, the following Patent Documents are known.

Patent Document 1 and 2 disclose methods for reducing defects by optimizing a buffer layer in the initial stage of crystal growth. Patent Document 3 discloses a method in which, by selecting epilayer growth conditions, micropipes and other such defects are prevented from reaching the surface by filling the micropipes in part way through the process. In addition, Patent Document 4 discloses a method for reducing carrot defects in the epilayer surface using processes for suspending the epitaxial growth of the silicon carbide layer and performing etching, thereby decreasing the thickness of the epilayer and stopping carrot defects, and then subsequently regrowing a second epitaxial layer of silicon carbide.

Patent Document 5 discloses a method for reducing a reverse leakage mode by forming an oxide layer over defects in the front surface of the SiC underlying substrate using a method of anodization, the thereafter forming the Schottky electrode.

### PRIOR ART DOCUMENTS

### Patent Documents

[Patent Document 1] Japanese Laid-Open Patent Application No. 2009-295728

[Patent Document 2] Japanese Laid-Open Patent Application No. 2009-88223

[Patent Document 3] Japanese Laid-Open Patent Application No. 2003-332563

[Patent Document 4] Japanese Translation of PCT International Application No. 2007-525402

[Patent Document 5] Japanese Laid-Open Patent Application No. 2011-159814

### DISCLOSURE OF THE INVENTION

### Problems to be Solved by the Invention

However, the density of defects in the epilayer surface is already determined at the point in time at which the SiC epilayer is deposited on top of the SiC underlying substrate. Patent Documents 1 to 4 only address how to reliably remove devices having defects following epilayer formation, but none of these documents indicates methods for reducing the epilayer surface defects themselves, whereas according to the anodization method disclosed in Patent Document 5, it is possible to reduce the reverse leakage mode resulting from surface defects following epilayer formation, but the problem lies in the applicability of anodization to be used in mass production operations.

Therefore, a purpose of the present invention is to provide a silicon carbide semiconductor device and a method for manufacturing same that attempts to improve the non-defective rate of devices by reducing the density of crystal defects in the surface of a SiC epitaxial layer subsequent to the epitaxial layer being formed on a SiC underlying substrate.

### Means to Solve the Problems

To achieve the aforementioned purpose, the silicon carbide semiconductor device of the present invention having a first-conductivity-type silicon carbide semiconductor epitaxial layer layered on a main surface of a first-conductivity-type silicon carbide semiconductor substrate, the silicon carbide semiconductor device being characterized in that a recrystallized layer is provided on the surface of the silicon carbide semiconductor substrate on which the silicon carbide semiconductor epitaxial layer is layered, and/or the surface of the silicon carbide semiconductor epitaxial layer.

In the silicon carbide semiconductor device of the present invention, it is preferable that the recrystallized layer be selectively formed in a location such that the recrystallized layer covers over a crystal defect which penetrates through the silicon carbide semiconductor epitaxial layer.

In the silicon carbide semiconductor device of the present invention, it is preferable that the silicon carbide semiconductor device be either a silicon carbide Schottky barrier diode or a silicon carbide MOSFET.

The method of manufacturing the silicon carbide semiconductor device of the present invention in which a first-conductivity-type silicon carbide semiconductor epitaxial layer is formed on a main surface of a first-conductivity-type silicon carbide semiconductor substrate, the silicon carbide semiconductor device manufacturing method being characterized by having a step for supplying strain energy to a surface layer of the surface of the silicon carbide semiconductor substrate on which the silicon carbide semiconductor epitaxial layer is formed, and/or the surface of the silicon carbide semiconductor epitaxial layer, and thereafter forming a recrystallized layer by adding a heat treatment for recrystallizing the surface layer to which the strain energy is supplied.

In the method of manufacturing the silicon carbide semiconductor device of the present invention, it is preferable that the means for providing the strain energy be ion implantation, plasma treatment, electron beam irradiation, or proton irradiation.

In the method of manufacturing the silicon carbide semiconductor device of the present invention, it is preferable that an ion species used in the ion implantation be an ion species of the same conductivity type as the silicon carbide semiconductor substrate.

In the method of manufacturing the silicon carbide semiconductor device of the present invention, it is preferable that the ion species used in the ion implantation be any ion species selected from among C, Si and Ge, which are elements having a valence of 4.

In the method of manufacturing the silicon carbide semiconductor device of the present invention, it is preferable that the ion species used in the ion implantation be a noble gas element.

In the method of manufacturing the silicon carbide semiconductor device of the present invention, it is preferable that the noble gas element be any element selected from among He, Ne, and Ar.

In the method of manufacturing the silicon carbide semiconductor device of the present invention, it is preferable that the heat treatment for recrystallizing the surface layer be a heat treatment in which either a high-frequency induction heating method or a laser irradiation method is used.

In the method of manufacturing the silicon carbide semiconductor device of the present invention, it is preferable that the heat treatment for recrystallizing the surface layer be a heat treatment at a temperature of between 1600° C. to 2000° C. for between 30 to 180 seconds in order to reduce carrot defects.

### Advantageous Effects of the Invention

According to the present invention, surface defects can be eliminated by introducing strain energy to either the underlying substrate or the epitaxial layer of the silicon carbide semiconductor to form a strain layer, and recrystallizing the strain layer using heat treatment, thereby making it possible to obtain a crystal defect free device formation region, and to provide a silicon carbide semiconductor having outstanding electrical characteristics.

### BRIEF DESCRIPTION OF THE DRAWINGS

FIG. 1 is schematic diagrams showing SiC-SBD manufacturing processes according to a first embodiment of the present invention.

FIG. 2 is cross-sectional schematic diagrams showing modes of crystal defects formed in a SiC semiconductor substrate.

FIG. 3 is transmission electron microscope images showing crystal defects formed in a SiC epilayer.

FIG. 4 is schematic diagrams showing SiC-SBD manufacturing processes according to another embodiment of the present invention.

FIG. 5 is schematic diagrams showing conventional SiC-SBD manufacturing processes.

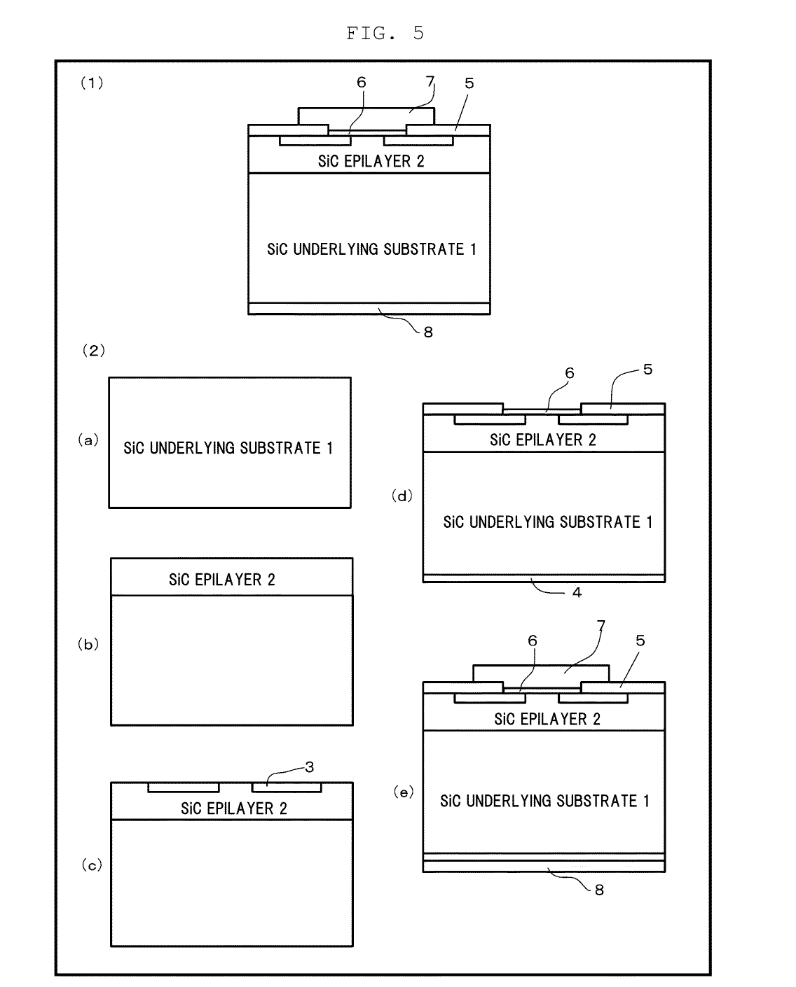

### BEST MODE FOR CARRYING OUT THE INVENTION

Examples related to the silicon carbide semiconductor device and the method for manufacturing same of the present invention will be explained in detail below by referring to the drawings. In the present specification and accompanying drawings, a layer or a region designated by either n or p signifies that each electron or hole is a majority carrier. A plus sign or minus sign attached to the n and/or p signifies that the impurity concentration is respectively relatively high or low. Furthermore, in the following explanation of the examples and the accompanying drawings, the same numerals and characters will be given to configurations that are the same, and duplicative explanations will not be provided. For ease of viewing and comprehension, the accompanying drawings explained in accordance with the examples are not drawn to scale or in the correct proportions. The present invention, to the extent that it does not depart from the main point thereof, is not limited to the descriptions of the examples explained below.

In order to reduce the defect density of the SiC epilayer, the silicon carbide semiconductor device of the present invention can be provided with a recrystallized layer obtained by forming a strain layer in either the SiC underlying substrate or the SiC epilayer, and thereafter recrystallizing the strain layer using heat treatment.

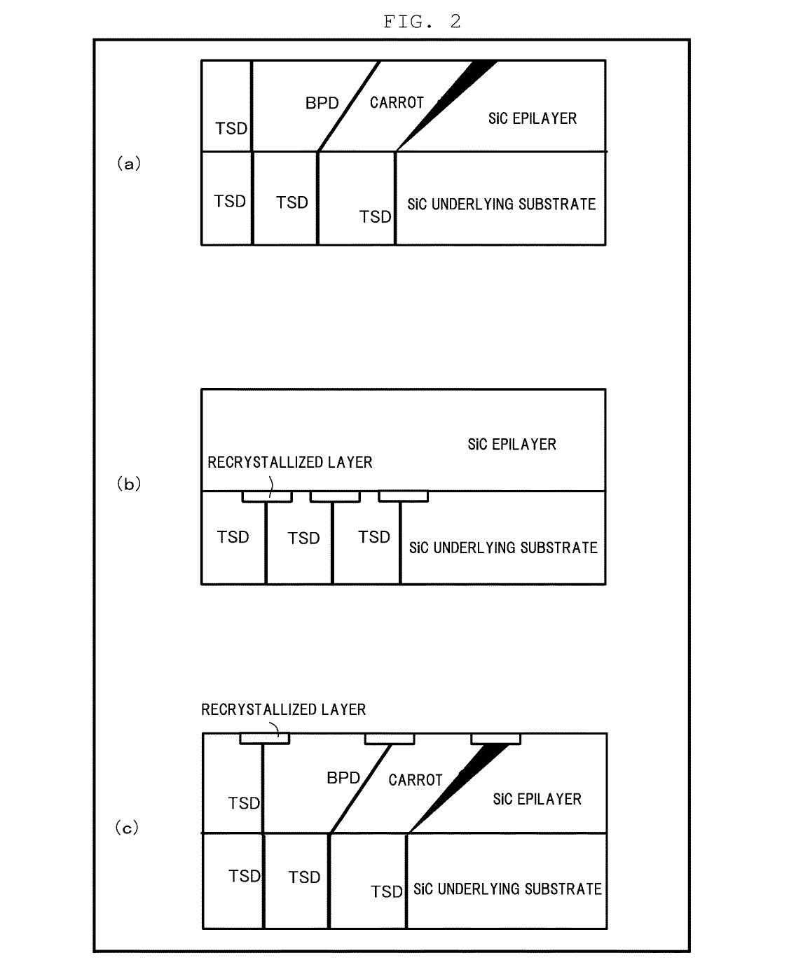

In FIG. 2(a), which schematically shows a cross-section of a SiC semiconductor device according to a conventional manufacturing method that forms a SiC epilayer without introducing a strain layer, threading screw dislocations (TSD) that formed in the SiC underlying substrate either have propagated to the epilayer surface as it is, or have propagated to the epilayer surface in accordance with the crystal defect type having been converted to basal plane dislocations (BPD) or carrot defects. FIG. 2(b) schematically shows a cross-section of a SiC semiconductor device in which, in accordance with the manufacturing method of the present invention, a recrystallized layer is formed by partial recrystallization so as to at least cover surface defects in the SiC underlying substrate, the ends of the defects in the underlying substrate are blocked by the recrystallized layer, and the propagation of defects into the epilayer is suppressed. FIG. 2(c) schematically shows a cross-section of a SiC semiconductor device that reduces defect density by forming a SiC epitaxial layer on the SiC underlying substrate and partially recrystallizing the surface of the epitaxial layer in accordance with the manufacturing method of the present invention.

In the aspect of FIG. 2(a), crystal defects are also formed in the surface of the SiC epilayer; i.e., the device formation region, but according to the aspects of FIGS. 2(b) and 2(c), it is possible to reduce the defect density in the device formation region.

Consequently, it is preferable that the recrystallized layer in the silicon carbide semiconductor device of the present invention be the aspect of FIG. 2(b) and/or FIG. 2(c) described above.

The recrystallized layer may be formed on the SiC underlying substrate either partially or completely.

The recrystallized layer provided on the silicon carbide semiconductor device of the present invention will be explained in more detail below.

In the manufacture of the SiC semiconductor device of the present invention, for example, an n-type SiC epilayer (doping concentration of 1×10¹⁶ cm⁻³, epilayer thickness of 10 μm) can be formed on the Si surface of the SiC underlying substrate (n-doped, resistivity of 20 mΩ cm, off-axis 4°), Al can be implanted into the surface of the SiC epilayer in three stages (first stage: 5×10¹⁴ cm⁻²/350 keV, second stage: 3×10¹⁴ cm⁻²/250 keV, and third stage: 2×10¹⁴ cm⁻²/100 keV, implantation temperature of 500° C.), strain energy can be introduced to the crystal lattice in accordance with elastic collisions of ions, and a strain layer can be formed on the crystal lattice. Thereafter, for example, the strain layer can be recrystallized using high-frequency induction heating (at 1600° C. for 180 seconds) to form a recrystallized layer.

According to the manufacturing method described above, it is possible to reduce the defect density detected immediately after SiC epitaxial growth using an optical surface inspection apparatus as being from around 5/cm² to 2/cm² or less by following the recrystallization process.

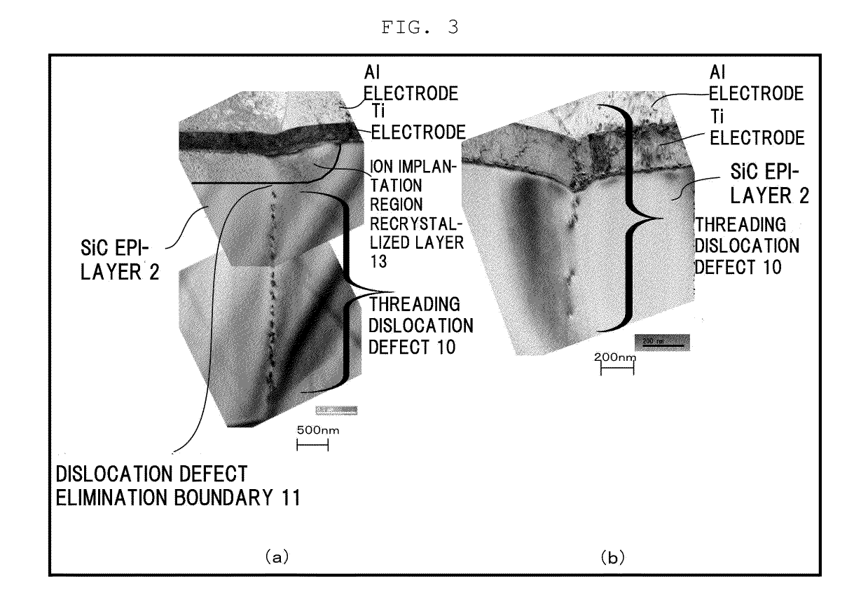

FIG. 3(a) shows a transmission electron microscope (TEM) image of a cross-section of a SiC epitaxial layer fabricated using the aforementioned manufacturing conditions. It is clear that a threading dislocation defect 10 extending to the surface of the epilayer 2 (top of FIG. 3(a)) from inside the SiC underlying substrate (bottom of FIG. 3(a)) is eliminated at the ion implantation region boundary 11, and does not reach the surface of the SiC epilayer 2. On the other hand, FIG. 3(b) shows a TEM image of a cross-section of a SiC epilayer that has been heat treated without implanting ions (subjected to heat treatment without providing strain energy). It is clear that a threading dislocation defect 10 extending from the substrate reaches the surface of the SiC epilayer 2, and is inhibiting the formation of a silicide layer. In addition, because the silicide layer is not well formed on top of the threading dislocation defect 10 that reached the surface, a crack-shaped defect (the zigzagging line) has formed in the silicide.

Thus, the formation of a strain layer in the SiC epilayer and subsequent recrystallization of the strain layer makes it possible to eliminate crystal defects in the recrystallized layer.

In the method of manufacturing the silicon carbide semiconductor device described above, a recrystallized layer is obtained using ion implantation and high-frequency induction heating, but the present invention is not limited thereto.

A method of forming the recrystallized layer of the silicon carbide semiconductor device of the present invention will be explained in detail below.

A process for forming a recrystallized layer on either the SiC epilayer or the SiC underlying substrate comprises a process for forming a strain layer by providing strain energy, and a process for heat treating the strain layer to perform recrystallization. Table 1 is a list of strain introduction methods and recrystallization methods related to the present invention. Ion implantation, plasma treatment, electron beam irradiation, and proton irradiation can be used as methods for forming the strain layer. High-frequency induction heating, laser annealing, and other such heat treatments can be used as recrystallization methods.

TABLE 1

| | | | Recrystallization |
|---|---|---|---|
| Strain Layer Formation Methods | | | Methods |
| Plasma Treatment | | | High-Frequency |
| Ion Implantation | n type | N (nitrogen), P | Induction Heating, |
| | | (phosphorus) | Laser Annealing |
| | p type | B (boron), Al | |
| | Group 4 | C, Si | |
| | Noble Gases | He, Ar | |

Electron Beam Irradiation
Proton Irradiation

[Ion Implantation]

In the manufacturing process of the silicon carbide semiconductor device of the present invention, any of an n-type dopant (N₂, P and so forth), a p-type dopant (B, Al, and so forth), a Group 4 element (C, Si, Ge, and so forth) or a noble gas element (He, Ne, Ar, and so forth) can be implanted in either the SiC epilayer or the SiC underlying substrate to form a strain layer. When an element having a large mass number is used, an abundance of strain energy can be introduced. However, in a case where either an n-type dopant or a p-type dopant is used, the dosage must be limited so as not to impact the electrical characteristics of the device. The depth of the strain layer and/or a degree of strain can be changed by the dosage and an accelerating voltage. In particular, according to the multistage ion implantation method in which ion implantation is performed a plurality of times by changing the dosage and the accelerating voltage, it is also possible to change a distribution of the strain energy. For example, in Al ion implantation, a strain layer having a depth of approximately 1 μm can be formed using three-stage ion implantation (first stage: 5×10¹⁴ cm⁻²/350 keV, second stage: 3×10¹⁴ cm⁻²/250 keV, and third stage: 2×10¹⁴ cm⁻²/100 keV). In the implantation of P in an n-type SiC substrate, a strain layer having a depth of approximately 0.2 μm can be formed using two-stage ion implantation (first stage: 1.5×10¹³ cm⁻²/70 keV, second stage: 1.5×10¹³ cm⁻²/40 keV). In an SBD, MOSFET, or other such surface device, a strain layer having a depth of around 1 μm is sufficient, and it is undesirable for more frequent multistage ion implantation to be used to increase the depth of the strain layer due to the increase in costs. There are no special limitations on the temperature of the substrate at ion implantation, which may be 500° C., the temperature commonly used in the semiconductor process, but a high temperature is not necessarily required, and even room temperature is also suitable.

[Plasma Treatment]

In the manufacturing process of the silicon carbide semiconductor device of the present invention, the strain layer can be formed by exposing either the SiC epilayer or the SiC underlying substrate to an H, Ar, CF₄ or other such plasma. There are no special limitations of a plasma apparatus, and an inductively coupled plasma apparatus, a capacitively-coupled plasma apparatus, and a microwave plasma apparatus or the like can be used. For example, according to a capacitively-coupled plasma apparatus, strain can be provided to the entire surface of the SiC semiconductor device by a plasma treatment at 300 watts or more for 60 seconds.

[Electron Beam Irradiation]

In the manufacturing process of the silicon carbide semiconductor device of the present invention, the strain layer can be formed by irradiating an electron beam onto either the SiC epilayer or the SiC underlying substrate. Because of the high penetrability of the electron beam, strain is provided down to a depth of several hundred microns at the same accelerating voltage as the silicon semiconductor process. Therefore, for the present purpose, it is preferable that an electron beam having weaker penetrability be obtained using either an electron gun having a low accelerating voltage or an aluminum plate or other such moderator, and that the depth of the strain layer and/or the amount of energy be controlled in accordance with the number of irradiations.

[Proton Irradiation]

In the manufacturing process of the silicon carbide semiconductor device of the present invention, the strain layer can be formed by irradiating protons accelerated by a tandem Van de Graaff accelerator onto either the SiC epilayer or the SiC underlying substrate. For example, a strain region having a peak at a depth in the vicinity of 3 μm from the surface can be formed by irradiating protons at a dosage of 1×10¹³ atoms/cm² and an accelerating energy of 0.5 MeV.

[Heat Treatment Method]

High-frequency induction heating or laser annealing method can be used as the heat treatment method. It is preferable that the heat treatment be performed at between 1600° C. and 2000° C. for between 30 and 180 seconds, and more preferably at between 1700° C. and 2000° C. for between 30 and 150 seconds. It is preferable that the heat treatment not be performed at less than 1600° C. because of the high likelihood of incomplete recrystallization and crystal defects remaining, and not at 2000° C. or higher because dopant sublimation causes changes in electrical characteristics. When using laser annealing, by selective laser irradiation according to a defect map prepared using a surface defect evaluation apparatus subsequent to epilayer formation, it is possible to selectively recrystallize the SiC surface so as to cover only the defect portions as shown in FIG. 2(b) and FIG. 2(c).

A point that should be noted in the heat treatment process is “step bunching,” in which the unevenness of the substrate surface intensifies. For example, because each layer of atoms grows laterally in an epitaxial layer grown on an underlying substrate inclined around 8 degrees from the (0001) plane of a 4H—SiC in the [11-20] direction, growth steps at the ends of the layers of atoms become integrated under certain conditions, and surface unevenness becomes intense. Step bunching can be prevented, for example, by growing a carbon film having a thickness of 30 nm on the substrate surface prior to heat treatment. Subsequent to heat treatment, no-longer-needed carbon film can be peeled off. CMP smoothing may also be used after ion implantation. However, caution must be taken so that the CMP polishing depth is less than the depth of the ion implantation region so as not to overgrind the recrystallized layer.

### EXAMPLES

### Example 1

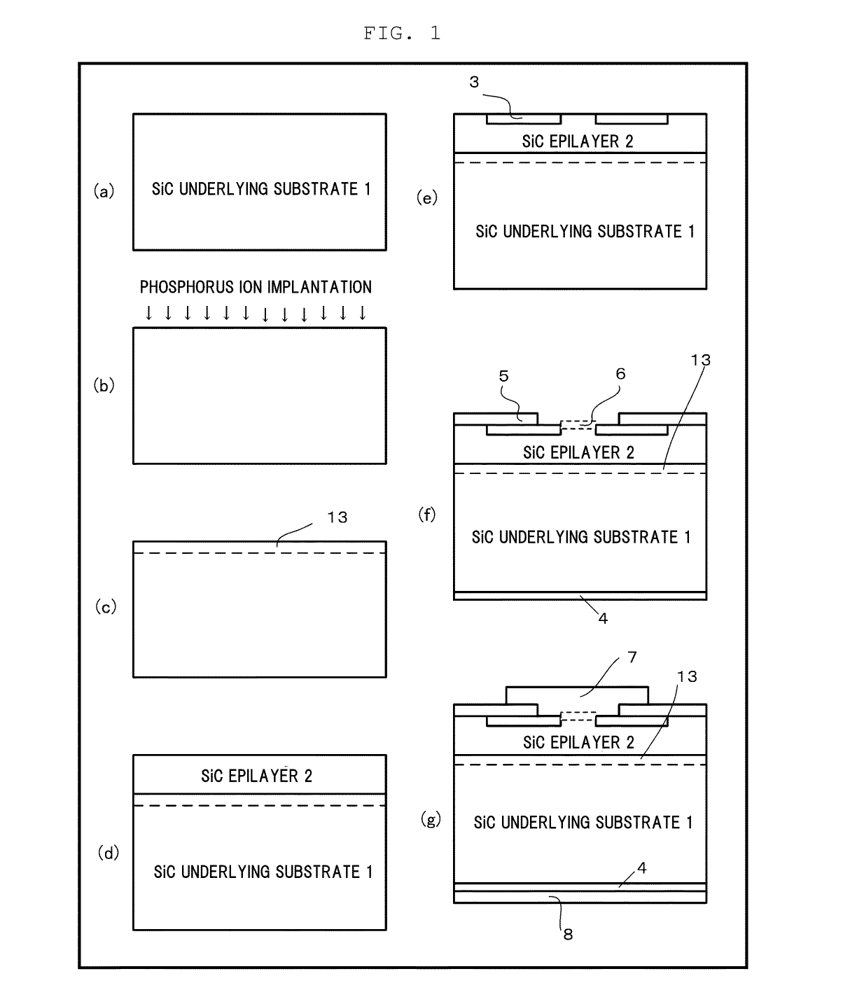

SiC-SBD was fabricated in accordance with the manufacturing process shown in FIG. 1.

As step (b), phosphorus was implanted over the entire Si surface of the SiC underlying substrate 1 in two stages to form an ion implantation region (strain layer). At this point, first stage implantation was performed at a dosage of 2×10¹⁵ cm⁻² and an accelerating energy of 250 keV, and second stage implantation was performed at a dosage of 5×10¹⁴ cm⁻² and an accelerating energy of 70 keV. Implantation was performed at room temperature. Next, as step (c), heat treatment using high-frequency induction heating was performed at a temperature of 1600° C. for 180 seconds under a normal pressure Ar environment, and the ion implantation region (strain layer) introduced in step (b) was recrystallized to form the recrystallized layer 13 (the heat treatment at 1600° C. for 180 seconds may be substituted with a heat treatment at 2000° C. for 30 seconds). Although not shown in the drawing, a carbon film (30 nm thick) was formed on the substrate surface subsequent to ion implantation to prevent surface roughness due to step bunching, and was peeled off after heat treatment at 1600° C.

As step (d), a SiC epilayer 2 was formed. For the SiC epilayer 2, first a buffer layer (n doping, carrier concentration of 1×10¹⁸ cm⁻³ and thickness of approximately 0.5 μm) (not-shown) was formed, after which an n-type SiC (n⁻-type doping, carrier concentration of 1×10¹⁶ cm⁻³ and thickness of approximately 10 μm) was grown epitaxially. A surface defect inspection was performed after forming the SiC epilayer 2, and it was confirmed that the normal defect level of four defects/cm² had been reduced to 1.5 defects/cm².

As step (e), ion implantation of a p-type dopant Al was performed to form p-type regions 3 using a oxide film mask (not-shown) formed on the surface of the SiC epilayer 2 by photoetching. The ion implantation was performed in sequence having as implantation conditions 5×10¹² cm⁻²/350 keV in the first stage, 3×10¹² cm⁻²/150 keV in the second stage, and 2×10¹² cm⁻²/100 keV in the third stage. The implantation temperature was 500° C. Next, a 50 nm carbon film (not shown) was deposited on the surface of the SiC epilayer 2, and activation heat treatment was performed at 1600° C. for 180 seconds. Thereafter, the carbon film was removed. Next, as step (f), after forming an Ni film, heat treatment was performed at 1000° C. to form an Ni silicide film 4 on the back surface side. Next, photoetching was used to form a contact hole in an oxide film 5 on the front surface side, after which a 200-nm-thick Ti film to form a Schottky barrier electrode 6 was formed. After using photoetching to remove the Ti from the peripheral part of the contact hole, heat treatment was performed at 500° C. to form a Ti silicide. Finally, as step (g), a 5 μm-thick AlSi electrode 7 was formed on the front surface, and a photoetching process was used to remove the peripheral part. In addition, a Ti/Ni/Au electrode 8 was formed over the entire back surface side.

In Example 1 above, the surface defect density of the SiC underlying substrate 1 is reduced by forming a recrystallized layer on the front surface of the SiC underlying substrate 1 using P ion implantation and heat treatment at 1600° C., after which the SiC epilayer is formed, whereby the extension of defects from the SiC underlying substrate 1 to the SiC epilayer is prevented, and the non-defective rate of the SiC-SBD is improved.

### Example 2

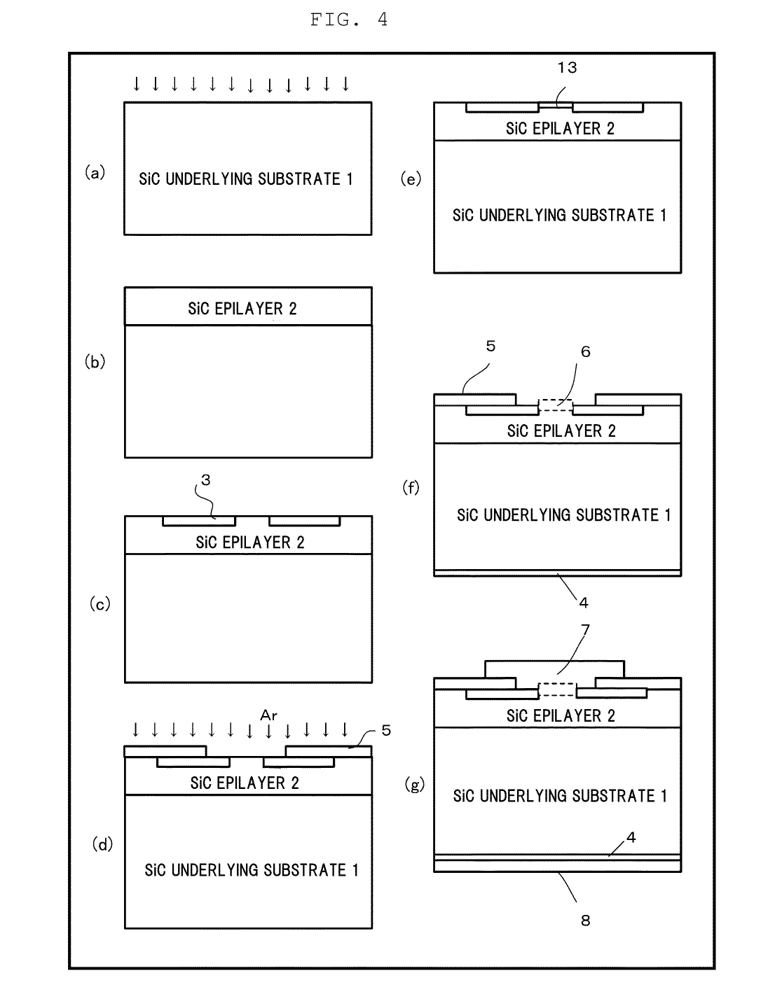

An SiC-SBD was fabricated in accordance with the manufacturing processes shown in FIG. 4.

As step (b), an n⁻-type SiC epilayer 2 (1×10¹⁶ cm⁻³, 10 μm) was formed on the Si surface of the SiC underlying substrate 1 (a buffer layer (1×10¹⁸ cm⁻³, 0.5 μm) may be formed here prior to forming the n⁻-type SiC epilayer 2). An inspection was performed using a surface defect evaluation apparatus subsequent to forming the n-SiC epilayer 2, and four defects/cm² were detected.

Next, ion implantation of Al was performed in three stages using an oxide film mask (not shown) formed on the surface of the SiC epilayer 2 by photoetching to form a voltage withstanding structure part. The p-type regions 3 were formed by performing ion implantation in sequence having as implantation conditions 5×10¹² cm⁻²/350 keV in the first stage, 3×10¹² cm⁻²/150 keV in the second stage, and 2×10¹² cm⁻²/100 keV in the third stage. The implantation temperature was 500° C. Next, as step (d), after forming an oxide film 5 over the entire surface, a photoetching process was used to open a portion on the inner circumference side of the voltage withstanding structure part, after which the ion implantation of Ar was performed in three stages. The ion implantation was performed at room temperature under a dosage of 1×10¹³ cm⁻²/350 keV in the first stage, 6×10¹² cm⁻²/150 keV in the second stage, and 4×10¹² cm⁻²/100 keV in the third stage. Next, as step (e), the front surface oxide film was removed, and a 40-nm carbon film (not shown) was formed on the front surface, followed by heat treatment using high-frequency induction heating under conditions of 1700° C. for 150 seconds.

Thereafter, a surface defect inspection was performed, and it was confirmed that the normal defect level of 4/cm² had been reduced to 1.5/cm².

As step (f), after forming an oxide film 5 on the surface of the SiC epilayer 2, and opening a contact part for a Schottky barrier electrode 6 by partially removing the oxide film using etching, a 200-nm-thick Ti film was formed as the metal of the Schottky barrier electrode 6, heat treatment was performed under conditions of 500° C. for 30 seconds to make a silicide, and a Schottky barrier junction having a prescribed Schottky barrier height was formed. Finally, as step (g), an AlSi electrode 7 was formed on the front surface, and a Ti/Ni/Au electrode 8 was formed on back surface.

In Example 2 above, a recrystallized layer was formed on the surface of the SiC epilayer 2 using Ar ion implantation and heat treatment at 1700° C., the surface defect density of the SiC epilayer 2 was reduced, and the non-defective rate of the SiC-SBD was improved.

In both Examples 1 and 2, the number of defects was reduced from the conventional surface defect density of 4/cm² to 1.5/cm², and the non-defective rate of an SBD having a 1200V withstand voltage was improved from 65% to 80%.

Basically, it was ascertained that the ion species of the ion implantation for forming the recrystallized layer 13 on the surface of the SiC epilayer 2 does not matter; implantation of an ion of a noble gas such as Ar, which has little effect on the stability of the subsequent process for forming the Schottky junction, is effective; other than ion implantation, plasma treatment, electron beam irradiation, and proton irradiation are effective; and laser annealing is also effective as a heat treatment.

### EXPLANATION OF NUMERALS AND CHARACTERS

1 SiC UNDERLYING SUBSTRATE
2 SiC EPILAYER
3 p-TYPE REGION
4 Ni SILICIDE FILM
5 OXIDE FILM
6 SCHOTTKY BARRIER ELECTRODE
7 AlSi ELECTRODE
8 Ti/Ni/Au ELECTRODE
10 THREADING DISLOCATION DEFECT
11 BOUNDARY BETWEEN RECRYSTALLIZED LAYER AND EPILAYER
13 RECRYSTALLIZED LAYER

1-3. (canceled)

4. A method of manufacturing a silicon carbide semiconductor device in which a first-conductivity-type silicon carbide semiconductor epitaxial layer is formed on a main surface of a first-conductivity-type silicon carbide semiconductor substrate, wherein the silicon carbide semiconductor device manufacturing method comprises:
a step for supplying strain energy to at least one of (i) a surface layer of the surface of the silicon carbide semiconductor substrate on which the silicon carbide semiconductor epitaxial layer is formed, and (ii) the surface of the silicon carbide semiconductor epitaxial layer,
a step for forming a carbon film on the surface layer, and
a step for forming a recrystallized layer by adding a heat treatment for recrystallizing the surface layer to which the strain energy is supplied.

5. The method of manufacturing the silicon carbide semiconductor device according to claim 4, wherein the strain energy is provided by one of: ion implantation, plasma treatment, electron beam irradiation and proton irradiation.

6. The method of manufacturing the silicon carbide semiconductor device according to claim 5, wherein an ion species used in the ion implantation is an ion species of a same conductivity type as the silicon carbide semiconductor substrate.

7. The method of manufacturing the silicon carbide semiconductor device according to claim 5, wherein an ion species used in the ion implantation is any ion species selected from a group consisting of the elements C, Si and Ge, which have a valence of 4.

8. The method of manufacturing the silicon carbide semiconductor device according to claim 5, wherein an ion species used in the ion implantation is a noble gas element.

9. The method of manufacturing the silicon carbide semiconductor device according to claim 8, wherein the noble gas element is any element selected from a group consisting of He, Ne, and Ar.

10. The method of manufacturing the silicon carbide semiconductor device according to claim 4, wherein the heat treatment for recrystallizing the surface layer is one of (i) a high-frequency induction heating method and (ii) a laser irradiation method.

11. The method of manufacturing the silicon carbide semiconductor device according to claim 10, wherein, in order to reduce carrot defects, the heat treatment for recrystallizing the surface layer is at a temperature of between 1600° C. to 2000° C. for between 30 to 180 seconds.

12. A silicon carbide semiconductor device comprising the recrystallized layer formed by the method of forming said recrystallized layer according to claim 4.
